(19) United States
(12) Patent Application Publication
(10) Pub. No.: US 2015/0255324 A1
(43) Pub. Date: Sep. 10, 2015

(54) SEAMLESS GAP-FILL WITH SPATIAL ATOMIC LAYER DEPOSITION

(71) Applicant: Applied Materials, Inc., Santa Clara, CA (US)

(72) Inventors: Ning LI, San Jose, CA (US); Victor NGUYEN, Novato, CA (US); Mihaela BALSEANU, Cupertino, CA (US); Li-Qun XIA, Cupertino, CA (US); Steven D. MARCUS, San Jose, CA (US); Haichun YANG, Santa Clara, CA (US); Keiichi TANAKA, San Jose, CA (US)

(21) Appl. No.: 14/630,757

(22) Filed: Feb. 25, 2015

Related U.S. Application Data
(60) Provisional application No. 61/948,940, filed on Mar. 6, 2014.

(51) Int. Cl. H01L 21/762; H01L 21/02; H01L 21/311

(52) U.S. Cl. CPC H01L 21/76224; H01L 21/31116; H01L 21/02274

(57) ABSTRACT

Embodiments disclosed herein generally relate to forming dielectric materials in high aspect ratio features. In one embodiment, a method for filling high aspect ratio trenches in one processing chamber is disclosed. The method includes placing a substrate inside a processing chamber, where the substrate has a surface having a plurality of high aspect ratio trenches and the surface is facing a gas/plasma distribution assembly. The method further includes performing a sequence of depositing a layer of dielectric material on the surface of the substrate and inside each of the plurality of trenches, where the layer of dielectric material is on a bottom and side walls of each trench, and removing a portion of the layer of dielectric material disposed on the surface of the substrate, where an opening of each trench is widened. The sequence repeats until the trenches are filled seamlessly with the dielectric material.

### CROSS-REFERENCE TO RELATED APPLICATIONS

This application claims priority to U.S. Provisional Patent Application Ser. No. 61/948,940, filed on Mar. 6, 2014, which herein is incorporated by reference.

BACKGROUND

1. Field

Embodiments disclosed herein generally relate to the processing of substrates, and more particularly, relate to methods for forming dielectric materials in high aspect ratio features.

2. Description of the Related Art

As the device density on integrated circuits continues to increase, the size and distance between device structures continue to decrease. The narrower widths in the gaps of the structures and the trenches between structures increase the ratio of height to width (i.e., the aspect ratio) in these formations. In other words, the continued miniaturization of integrated circuit elements is shrinking the horizontal width within and between these elements faster than their vertical height.

While the ability to make device structures with ever increasing aspect ratios has allowed more structures (e.g., transistors, capacitors, diodes, etc.) to be packed onto the same surface area of a semiconductor chip substrate, it has also created fabrication problems. One of these problems is the difficulty of completely filling the gaps and trenches in these structures without creating a void or seam during the filling process. Filling gaps and trenches with dielectric materials like silicon nitride or silicon oxide is necessary to electrically isolate nearby device structures from each other. If the gaps were left empty, there would be too much electrical noise, and current leakage for the devices to operate properly (or at all).

When gap widths are larger (and aspect ratios smaller) the gaps are relatively easy to fill with a rapid deposit of a dielectric material. The deposition material would blanket the sides and bottom of the gap and continue to fill from the bottom up until the crevice or trench was fully filled. As aspect ratios increased to 3:1 or above, however, it became more difficult to fill the deep, narrow trench without having a blockage start a void or seam in the fill volume.

Thus, there remains a need for methods for forming dielectric materials into gaps, trenches, and other device structures with high aspect ratios.

### SUMMARY

Embodiments disclosed herein generally relate to the processing of substrates, and more particularly, relate to methods for forming dielectric materials in high aspect ratio features. In one embodiment, a method for filling high aspect ratio trenches is disclosed. The method includes placing a plurality of substrates inside a processing chamber, where each substrate has a surface having a plurality of high aspect ratio trenches and the surface is facing a gas/plasma distribution assembly. The method further includes performing a sequence of depositing a layer of dielectric material on the surface of the substrate and inside each of the plurality of trenches, where the layer of dielectric material is on a bottom and side walls of each trench, and removing a portion of the layer of dielectric material disposed on the surface of the substrate, where an opening of each trench is widened. The method further includes repeating the sequence until the trenches are filled seamlessly with the dielectric material, where the sequence is performed in the processing chamber.

### BRIEF DESCRIPTION OF THE DRAWINGS

So that the manner in which the above recited features of the present invention can be understood in detail, a more particular description of the invention, briefly summarized above, may be had by reference to implementations, some of which are illustrated in the appended drawings. It is to be noted, however, that the appended drawings illustrate only typical implementations of this invention and are therefore not to be considered limiting of its scope, for the invention may admit to other equally effective implementations.

FIG. 1 is a cross sectional side view of a processing chamber according to one embodiment.

FIG. 2 is a perspective view of a carousel processing chamber according to one embodiment.

FIG. 3 is a schematic bottom view of a portion of a gas/plasma distribution assembly according to one embodiment.

FIG. 4 illustrates process steps for filling high aspect ratio features with a dielectric material according to one embodiment.

To facilitate understanding, identical reference numerals have been used, where possible, to designate identical elements that are common to the figures. It is contemplated that elements disclosed in one implementation may be beneficially used on other implementations without specific recitation.

### DETAILED DESCRIPTION

Embodiments disclosed herein generally relate to the processing of substrates, and more particularly, relate to methods for forming dielectric materials in high aspect ratio features. In one embodiment, a method for filling high aspect ratio trenches is disclosed. The method includes placing a substrate inside a processing chamber, where the substrate has a surface having a plurality of high aspect ratio trenches and the surface is facing a gas/plasma distribution assembly. The method further includes performing a sequence of depositing a layer of dielectric material on the surface of the substrate and inside each of the plurality of trenches, where the layer of dielectric material is on a bottom and side walls of each trench, and removing a portion of the layer of dielectric material disposed on the surface of the substrate, where an opening of each trench is widened. The method further includes repeating the sequence until the trenches are filled seamlessly with the dielectric material, where the sequence is performed in the processing chamber.

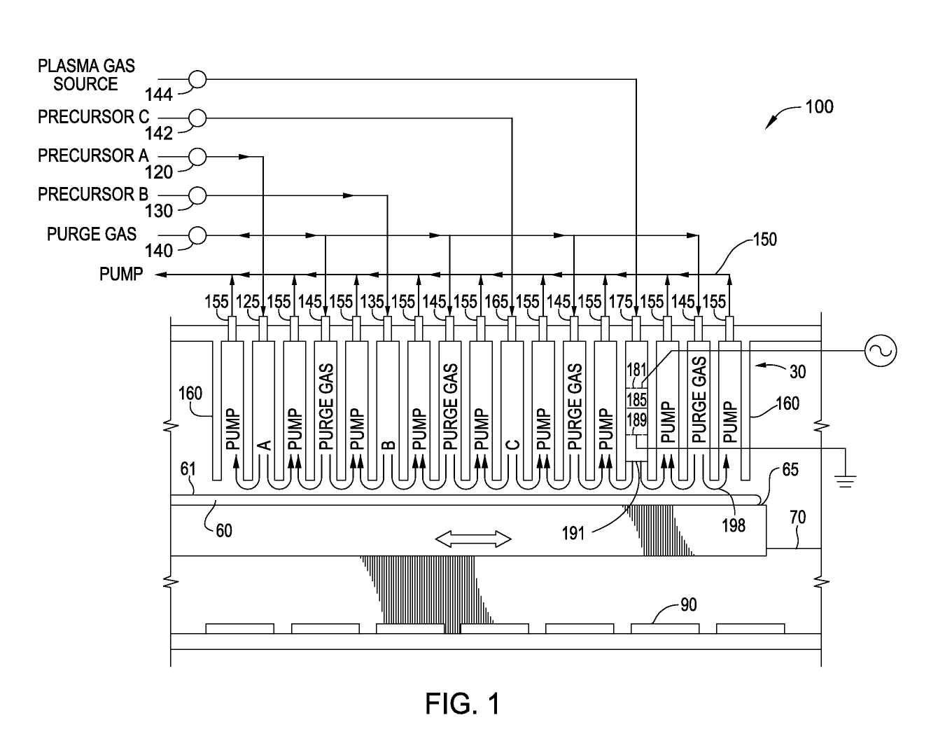

FIG. 1 is a cross sectional side view of a processing chamber 100 according to one embodiment. The processing chamber 100 is capable of performing both deposition and etching processes on one or more substrates 60. The processing chamber 100 includes a gas/plasma distribution assembly 30 capable of distributing one or more gases and/or a plasma across the top surface 61 of the substrate 60. The substrate 60 may have a plurality of trenches to be filled with a dielectric material, such as silicon nitride or silicon oxide. The gas/plasma distribution assembly 30 includes a plurality of gas ports to transmit one or more gas streams and/or a plasma to the substrate 60 and a plurality of vacuum ports disposed between adjacent gas ports to transmit the gas streams out of the processing chamber 100.

In one embodiment, the gas/plasma distribution assembly includes a first precursor injector 120, a second precursor injector 130, a third precursor injector 142, a plasma injector 144 and a purge gas injector 140. The injectors 120, 130, 140, 142, 144 may be controlled by a system computer (not shown), such as a mainframe, or by a chamber-specific controller, such as a programmable logic controller. The precursor injector 120 injects a continuous or pulse stream of a reactive precursor of compound A into the processing chamber 100 through a gas port 125. The precursor injector 130 injects a continuous or pulse stream of a reactive precursor of compound B into the processing chamber 100 through a gas port 135. The precursor injector 142 injects a continuous or pulse stream of a reactive precursor of compound C into the processing chamber 100 through a gas port 165. The precursors A, B, C may be used to perform atomic layer deposition (ALD) of silicon nitride, silicon oxide, or other dielectric materials into the trenches formed on the substrate 60. The precursor A may contain silicon, precursor B may contain nitrogen and precursor C may contain oxygen. In one embodiment, there are only two precursors such as precursors A and B or precursors A and C.

The plasma injector 144 may inject a remote plasma into the processing chamber 100 through a plasma/gas port 175 to perform plasma etching on the substrate 60. The plasma injector 144 may inject an etchant gas, such as NF₃ into a plasma region 185 through the plasma/gas port 175, and the electrodes 187, 189 form an electrical field in the plasma region 185 and in turn create a plasma in the plasma region 185. Other type of plasma source may be used instead of electrodes 187, 189 to create a plasma in the plasma region 185. The purge gas injector 140 injects a continuous or pulse stream of a non-reactive gas or purge gas into the processing chamber 100 through a plurality of gas ports 145. The remote plasma or the plasma formed in the plasma region 185 may go through a showerhead 191. The showerhead 191 may be configured to control the directionality of the etching process by letting more or less plasma onto the substrate 60.

The purge gas removes reactive material and reactive by-products from the processing chamber 100. The purge gas is typically an inert gas, such as nitrogen, argon or helium. Gas ports 145 may be disposed between gas ports 125, 135, 165, 175 so as to separate the precursor compounds A, B, C and the plasma or etchant gas, thereby avoiding cross-contamination between the precursors and the plasma/etchant gas.

In another aspect, a remote plasma source (not shown) may be connected to the precursor injector 120, precursor injector 130 and precursor injector 142 prior to injecting the precursors into the processing chamber 100. The processing chamber 100 further includes a pumping system 150 connected to the processing chamber 100. The pumping system 150 may be configured to evacuate the gas streams out of the processing chamber 100 through one or more vacuum ports 155. The vacuum ports 155 may be disposed between gas ports 125, 135, 165, 175 so as to evacuate the gas streams out of the processing chamber 100 after the gas streams react with the substrate surface 61 and to further limit cross-contamination between the precursors and the plasma/etchant gas.

The processing chamber 100 includes a plurality of partitions 160 disposed between adjacent ports. A lower portion of each partition 160 extends close to the surface 61 of the substrate 60, for example, about 0.5 mm or greater from the surface 61. In this configuration, the lower portions of the partitions 160 are separated from the substrate surface 61 by a distance sufficient to allow the gas streams to flow around the lower portions toward the vacuum ports 155 after the gas streams react with the substrate surface 61. Arrows 198 indicate the direction of the gas streams. Since the partitions 160 operate as a physical barrier to the gas streams, the partitions 160 also limit cross-contamination between the precursors. A plurality of heaters 90 may be disposed below the substrate 60 to assist one or more processes performed in the processing chamber 100.

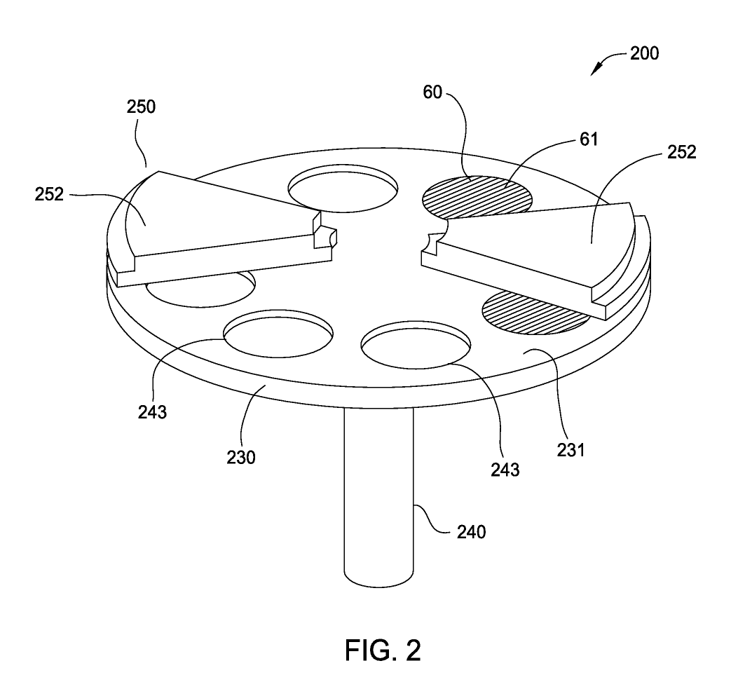

The processing chamber 100 may also include a shuttle 65 and a track 70 for transferring the substrates 60 through the processing chamber 100, passing under the gas/plasma distribution assembly 30. In the embodiment shown in FIG. 1, the shuttle 65 is moved in a linear path through the processing chamber 100. FIG. 2 shows an embodiment in which substrates are moved in a circular path through a carousel processing system.

FIG. 2 is a perspective view of a carousel processing chamber 200 according to one embodiment. The processing chamber 200 may include a susceptor assembly 230 and a gas/plasma distribution assembly 250. The susceptor assembly 230 has a top surface 231 and a plurality of recesses 243 formed in the top surface 231. Each recess 243 may support one substrate 60. In one embodiment, the susceptor assembly 230 has six recesses for supporting six substrates 60. Each recess 243 is sized so that the substrate 60 supported in the recess 243 has the top surface 61 that is substantially coplanar with the top surface 231 of the susceptor assembly 230. The susceptor assembly 230 may be rotated by a support shaft 240 during or between deposition/etching processes.

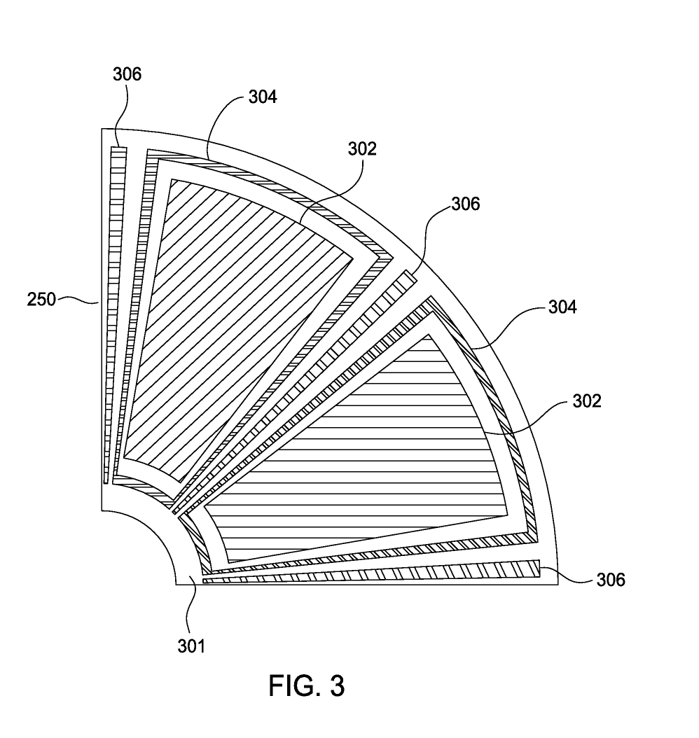

The gas/plasma distribution assembly 250 includes a plurality of pie-shaped segments 252. Portions of the gas/plasma distribution assembly 250 are removed to show the susceptor assembly 230 disposed below, as shown in FIG. 2. Instead of formed by the plurality of segments 252, the gas/plasma distribution assembly 250 may be formed in one piece having the same shape as the susceptor assembly 230. A portion of the gas/plasma distribution assembly 250 is shown in FIG. 3.

FIG. 3 is a schematic bottom view of a portion of the gas/plasma distribution assembly 250. The gas/plasma distribution assembly 250 has a surface 301 facing the susceptor assembly 230. A plurality of gas/plasma ports 302 may be formed in the surface 301. Surrounding each gas/plasma port 302 is a purge gas port 304 and between adjacent gas/plasma ports 302 is a vacuum port 306. The gas/plasma port 302 may have the same function as the gas/plasma port 125, 135, 165, 175, the purge gas port 304 may have the same function as the purge gas port 145, and the vacuum port 306 may have the same function as the vacuum port 155. In one embodiment, there are eight gas/plasma ports 302 disposed in the surface 301. In one embodiment, there are eight segments 252 forming the gas/plasma distribution assembly 250, each having one gas/plasma port 302. The portion of the gas/plasma distribution assembly 250 shown in FIG. 3 may be the combination of two segments 252. In one embodiment, one gas/plasma port 302 is used for distributing a plasma to perform plasma etching while the remaining seven ports 302 are used for distributing precursor gases for depositing dielectric materials into trenches formed on the substrates 60. In another embodiment, two gas/plasma ports 302 are used for distributing a plasma while the remaining six ports 302 are used for distributing precursor gases. In another embodiment, three gas/plasma ports 302 are use for distributing a plasma while the remaining five ports 302 are used for distributing precursor gases. In another embodiment, four gas/plasma ports 302 are used for distributing a plasma while the remaining four ports 302 are used for distributing precursor gases. The same precursor gas may go into more than one gas ports 302 and one or more precursors may go into one gas port 302.

The processing chamber 100 or 200 permits both deposition and etching in the processing chamber. During operation, the substrates 60 move under these spatially separated ports 302 and get sequential and multiple surface exposures to different chemical or plasma environment. Thus, layer by layer film growth in spatial ALD and surface etching processes become possible. During operation, a first layer of silicon nitride or silicon oxide in certain thickness may be deposited into the trenches as the substrate 60 is rotated under one or more gas ports 302. Then the substrate 60 is rotated so it is under a plasma port 302 and fluorine containing plasma removes a portion of the first layer. The etching mostly happens at the top of the trench because of the low concentration of plasma active components inside the trenches. In other words, the first layer deposited on the bottom and side walls of the trench is not affected. The plasma etch step makes the top of the trench open wider than the bottom of the trench. Next, another layer of silicon nitride or silicon oxide layer may be deposited into the trenches as the substrate 60 is rotated under one or more gas ports 302, and a portion of the second silicon nitride or silicon oxide layer near the top of the trenches is removed by the plasma etching process as the substrate 60 is rotated so it is under another plasma port 302. The deposition and etching processes may be repeated until the trenches are filled seamlessly with silicon nitride or silicon oxide. Seamlessly means there is substantially no void or seam inside the trench.

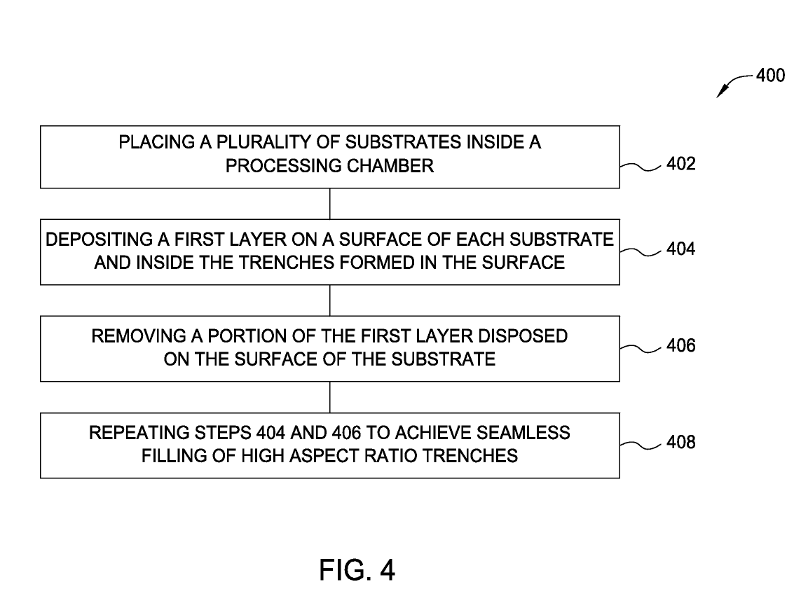

FIG. 4 illustrates process steps 400 for filling high aspect ratio features with a dielectric material according to one embodiment. At step 402, a plurality of substrates is placed inside a processing chamber, such as processing chamber 100 or processing chamber 200. The substrates may be placed on a susceptor assembly, such as the shuttle 65 or the susceptor assembly 230, under a gas/plasma distribution assembly, such as the gas/plasma distribution assembly 30, 250. In one embodiment, there are six substrates disposed on the susceptor assembly. Each of the plurality of substrates has a surface facing the gas/plasma distribution assembly and a plurality of high aspect ratio trenches are formed in the surface. At step 404, a first layer of dielectric material is deposited on the surface and inside the trenches. The first layer may be formed on the bottom and side walls of the trenches. In one embodiment, the first layer has a thickness ranging from about 50 angstroms to about 75 angstroms, such as about 50 angstroms. The first layer may be silicon nitride, silicon oxide or other dielectric material and may be formed as the substrate is placed under one or more gas ports of the gas/plasma distribution assembly. One or more precursor gases may flow out of the one or more gas ports and react with the surface of the substrate and with each other to form the first layer. The substrate may be moved by the susceptor assembly during deposition, or the substrate may be stationary under each one or more gas ports as the first layer is deposited.

Next, at step 406, a portion of the first layer disposed on the surface of the substrate is removed. The portion of the first layer disposed on the surface of the substrate may cause the trench to have a small opening, so the substrate is moved to a location under a plasma port, such as the plasma port 175, 302. A fluorine containing plasma is flowing out of the plasma port, and a portion of the first layer disposed on the surface of the substrate is etched back by about 10 to 30 percent, meaning 10 to 30 percent of the thickness of the first layer that is disposed on the surface of the substrate is removed. The portion of the first layer disposed on the bottom and side walls of the trench is not affected since there is a low concentration of radicals inside the trench. As the portion of the first layer disposed on the surface of the substrate is removed, the trench opening is widened, allowing easy filling of the trench.

Steps 404 and 406 may be repeated, as shown in step 408, such that a second layer is deposited on the first layer and inside the trench and a portion of the second layer disposed on the first layer is removed to widen the opening of the trench, until the high aspect ratio trench is seamlessly filled with the dielectric material. In one embodiment, step 408 includes repeating steps 404, 406 about 4 times to about 6 times, such as 6 times.

While the foregoing is directed to implementations of the present invention, other and further implementations of the invention may be devised without departing from the basic scope thereof, and the scope thereof is determined by the claims that follow.

1. A method for filling high aspect ratio trenches, comprising:
placing a plurality of substrates inside a processing chamber, wherein each substrate of the plurality of substrates has a surface having a plurality of high aspect ratio trenches and the surface is facing a gas/plasma distribution assembly;
performing a sequence of:
depositing a layer of dielectric material on the surface of the substrate and inside each of the plurality of trenches, wherein the layer of dielectric material is on a bottom and side walls of each trench; and
removing a portion of the layer of dielectric material disposed on the surface of the substrate, wherein an opening atop of each trench is widened; and
repeating the sequence until the trenches are filled seamlessly with the dielectric material, wherein the sequence is performed in the processing chamber.

2. The method of claim 1, wherein the substrates are placed on a susceptor assembly.

3. The method of claim 2, wherein the susceptor assembly has a top surface and a plurality of recesses are formed in the top surface, wherein each recess is configured to support one substrate.

4. The method of claim 3, wherein the plurality of recesses includes six recesses.

5. The method of claim 2, wherein the gas/plasma distribution assembly includes a surface facing the susceptor assembly, wherein a plurality of ports is formed in the surface of the gas/plasma assembly.

6. The method of claim 5, wherein the gas/plasma distribution assembly includes eight ports.

7. The method of claim 1, wherein the layer of dielectric material has a thickness ranging from about 50 angstroms to about 75 angstroms.

8. The method of claim 7, wherein the layer of dielectric material has a thickness of about 50 angstroms.

9. The method of claim 1, wherein the removing a portion of the layer of dielectric material includes removing about 10 to 30 percent of the layer of dielectric material.

10. The method of claim 9, wherein the removing a portion of the layer of dielectric material includes removing about 10 percent of the layer of dielectric material.

11. The method of claim 1, wherein the sequence is repeated 4 to 6 times.

12. The method of claim 11, wherein the sequence is repeated 6 times.

13. A method for filling high aspect ratio trenches, comprising:
placing a plurality of substrates inside a processing chamber, wherein each substrate of the plurality of substrates has a surface having a plurality of high aspect ratio trenches and the surface is facing a gas/plasma distribution assembly;
performing a sequence of:
placing each substrate under a first one or more ports of the gas/plasma distribution assembly to form a layer of dielectric material on the surface of the substrate and inside each of the plurality of trenches, wherein the layer of dielectric material is on a bottom and side walls of each trench; and
placing each substrate under a second one or more ports of the gas/plasma distribution assembly that are distinct from the first one or more ports to remove a portion of the layer of dielectric material disposed on the surface of the substrate, wherein an opening atop of each trench is widened; and
repeating the sequence until the trenches are filled seamlessly with the dielectric material, wherein the sequence is performed in the processing chamber.

14. The method of claim 13, wherein the gas/plasma distribution assembly includes a surface facing the surface of each substrate, wherein the first and second one or more ports are formed in the surface of the gas/plasma assembly.

15. The method of claim 14, wherein the gas/plasma distribution assembly includes eight ports.

16. The method of claim 13, wherein the layer of dielectric material has a thickness ranging from about 50 angstroms to about 75 angstroms.

17. The method of claim 16, wherein the layer of dielectric material has a thickness of about 50 angstroms.

18. The method of claim 13, wherein the removing a portion of the layer of dielectric material includes removing about 10 to 30 percent of the layer of dielectric material.

19. The method of claim 18, wherein the removing a portion of the layer of dielectric material includes removing about 10 percent of the layer of dielectric material.

20. The method of claim 13, wherein the sequence is repeated 4 to 6 times.
